(19) United States
(12) Patent Application Publication
(10) Pub. No.: US 2026/0096158 A1
(43) Pub. Date: Apr. 2, 2026

(54) SEMICONDUCTOR DEVICES INCLUDING GATE ELECTRODES

(71) Applicant: SAMSUNG ELECTRONICS CO., LTD., Suwon-si (KR)

(72) Inventors: Seunguk Han, Suwon-si (KR); Jinwoo Han, Suwon-si (KR); Taegyu Kang, Suwon-si (KR)

(73) Assignee: SAMSUNG ELECTRONICS CO., LTD., Suwon-si (KR)

(21) Appl. No.: 19/268,205

(22) Filed: Jul. 14, 2025

(30) Foreign Application Priority Data
Oct. 2, 2024 (KR) 10-2024-0133866

(51) Int. Cl. H10D 62/10; H01L 23/00; H10B 12/00; H10D 64/27; H10D 80/30

(52) U.S. Cl. CPC H10D 62/102; H10B 12/482; H10B 12/50; H10D 62/115; H10D 64/519; H10D 80/30; H10W 90/792

(57) ABSTRACT

A semiconductor device is provided. The device includes: an active layer extending in a first horizontal direction, the active layer including a first source/drain region, a channel region, and a second source/drain region sequentially arranged along the first horizontal direction; a bit line extending in a vertical direction and connected to the first source/drain region; an information storage structure connected to the second source/drain region; a gate electrode surrounding the active layer and extending in a second horizontal direction intersecting the first horizontal direction, wherein the gate electrode includes a first recessed region overlapping the first source/drain region along the vertical direction; an insulating pattern filling the first recessed region; and a gate dielectric layer provided between the active layer and the gate electrode, and surrounding the active layer.

### CROSS-REFERENCE TO RELATED APPLICATION(S)

This application claims priority to Korean Patent Application No. 10-2024-0133866, filed on Oct. 2, 2024, in the Korean Intellectual Property Office, the disclosure of which is incorporated by reference herein in its entirety.

### BACKGROUND

The present disclosure relates to semiconductor devices including gate electrodes.

As the demand for high performance, high speed, and/or multi-functionality of semiconductor devices increases, integration of semiconductor devices is also increasing. In manufacturing semiconductor devices with fine patterns to provide increased integration of semiconductor devices, it is required to implement patterns having fine widths or fine separation distances. In addition, as the size of semiconductor devices decreases, gate-induced drain leakage (GIDL) becomes an issue.

### SUMMARY

One or more example embodiments provide a semiconductor device including gate electrodes.

According to an aspect of an example embodiment, a semiconductor device includes: an active layer extending in a first horizontal direction, the active layer including a first source/drain region, a channel region, and a second source/drain region sequentially arranged along the first horizontal direction; a bit line extending in a vertical direction and connected to the first source/drain region; an information storage structure connected to the second source/drain region; a gate electrode surrounding the active layer and extending in a second horizontal direction intersecting the first horizontal direction, the gate electrode includes a first recessed region overlapping the first source/drain region along the vertical direction; an insulating pattern filling the first recessed region; and a gate dielectric layer provided between the active layer and the gate electrode, and surrounding the active layer.

According to another aspect of an example embodiment, a semiconductor device includes: an active layer extending in a first horizontal direction, the active layer including a first source/drain region, a channel region, and a second source/drain region sequentially arranged along the first horizontal direction; a bit line extending in a vertical direction and connected to the first source/drain region; an information storage structure connected to the second source/drain region; a gate electrode surrounding the active layer and extending in a second horizontal direction intersecting the first horizontal direction; and a gate dielectric layer provided between the active layer and the gate electrode, and surrounding the active layer. The gate electrode includes a recessed region overlapping the first source/drain region along the vertical direction. The first source/drain region has a first cross-section perpendicular to the first horizontal direction. The gate electrode has a second cross-section perpendicular to the first horizontal direction. A ratio of an area of the second cross-section to an area of the first cross-section decreases as distance from the channel region increases.

According to another aspect of an example embodiment, a semiconductor device includes: active layers extending in a first horizontal direction and spaced apart from each other along a second horizontal direction intersecting the first horizontal direction, the active layers including first source/drain regions, second source/drain regions, and channel regions provided between the first source/drain regions and the second source/drain regions along the first horizontal direction; bit lines extending in a vertical direction and connected to the first source/drain regions of the active layers; an information storage structure connected to the second source/drain regions of the active layers; a gate electrode surrounding the active layers and extending in the second horizontal direction, wherein the gate electrode includes recessed regions overlapping the first source/drain regions of the active layers along the vertical direction; insulating patterns filling the recessed regions; and gate dielectric layers provided between the active layers and the gate electrode, and surrounding the active layers.

### BRIEF DESCRIPTION OF DRAWINGS

The above and other aspects, features, and advantages will be more apparent from the following description of example embodiments, taken in conjunction with the accompanying drawings, in which:

FIG. 1 is a schematic perspective view of a semiconductor device according to an example embodiment;

FIG. 2 is a circuit diagram of a memory cell in a memory cell area according to an example embodiment;

FIG. 3 is a schematic perspective view of a semiconductor device according to an example embodiment;

FIG. 4 is a plan view of a semiconductor device according to an example embodiment;

FIG. 5A is a vertical cross-sectional view of the semiconductor device illustrated in FIG. 4, taken along line I-I′ according to an example embodiment;

FIG. 5B is a vertical cross-sectional view of the semiconductor device illustrated in FIG. 4, taken along line II-II′ according to an example embodiment;

FIG. 5C is a vertical cross-sectional view of the semiconductor device illustrated in FIG. 4, taken along line III-III′ according to an example embodiment;

FIGS. 6 to 9 are plan views of semiconductor devices according to example embodiments;

FIGS. 10A, 10B, 10C, 10D and 10E are drawings illustrating a process sequence of a method of manufacturing a semiconductor device according to an example embodiment;

FIG. 11 is a vertical cross-sectional view of a semiconductor device according to an example embodiment;

FIG. 12A is an enlarged view of a portion of the semiconductor device illustrated in FIG. 11 according to an example embodiment; and

FIG. 12B is an enlarged view of a portion of the semiconductor device illustrated in FIG. 12A according to an example embodiment.

### DETAILED DESCRIPTION

Hereinafter, example embodiments will be described with reference to the accompanying drawings. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. It will be also understood that, even if a certain step or operation of manufacturing an apparatus or structure is described later than another step or operation, the step or operation may be performed later than the other step or operation unless the other step or operation is described as being performed after the step or operation. The same reference numerals are used to denote the same elements in the drawings, and repeated descriptions thereof will be omitted.

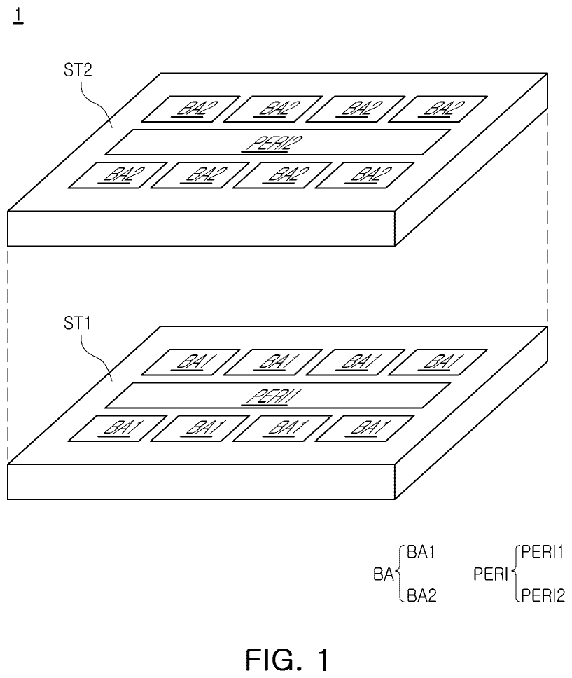

FIG. 1 is a schematic perspective view of a semiconductor device according to an example embodiment.

Referring to FIG. 1, a semiconductor device 1 according to an example embodiment may include a first structure ST1 and a second structure ST2 vertically overlapping the first structure ST1. The second structure ST2 may be disposed on the first structure ST1.

In an example embodiment, the first structure ST1 may be a first chip structure including memory cells MC, and the second structure ST2 may be a second chip structure including peripheral circuits capable of operating the memory cells MC. The first structure ST1 and the second structure ST2 may be formed by being bonded by a bonding process such as a wafer bonding process. Therefore, the first structure ST1 may be in contact with and bonded to the second structure ST2.

The semiconductor device 1 may include a plurality of banks BA and a peripheral circuit area PERI. The peripheral circuit area PERI may include a first peripheral circuit area PERI1 in the first structure ST1 and a second peripheral circuit area PERI2 in the second structure ST2. The peripheral circuit area PERI may be a peripheral circuit area in which peripheral circuits for input/output of data or commands, or input of power/ground are disposed.

Each of the plurality of banks BA may include a first bank area BA1 in the first structure ST1 and a second bank area BA2 in the second structure ST2.

The first bank area BA1 in the first structure ST1 may include memory cell areas. The memory cell areas may include memory cells MC. The memory cell areas may be arranged in an X-direction and a Y-direction. The X-direction and the Y-direction may be perpendicular to each other. The X-direction and the Y-direction may be referred to as horizontal directions, and a Z-direction that is perpendicular to each of the X-direction and the Y-direction may be referred to as a vertical direction.

The second bank area BA2 in the second structure ST2 may include core circuit areas. The core circuit areas may be arranged in the X-direction and the Y-direction. The core circuit areas may include a sense amplifier, a sub-word line driver, and the like.

The first peripheral circuit area PERI1 and the second peripheral circuit area PERI2 may include a control circuit capable of controlling the sense amplifier and the sub-word line driver.

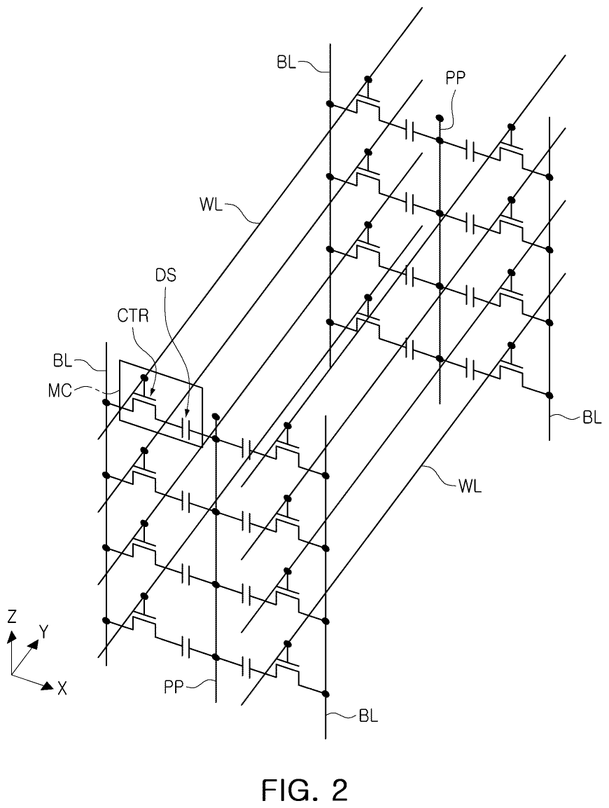

FIG. 2 is a circuit diagram of a memory cell of a memory cell area according to an example embodiment.

Referring to FIG. 2, the memory cell area may include memory cells MC arranged in the X-direction and the Y-direction, word lines WL connected to the memory cells MC and extending in the Y-direction, and bit lines BL connected to the memory cells MC and extending in the vertical direction.

Each of the memory cells MC may include a cell transistor CTR and an information storage element DS that may function as an information storage element. In a memory such as a dynamic random access memory (DRAM), the information storage element DS may be a cell capacitor that may store information. Adjacent information storage elements DS may share a plate electrode PP. For example, the plate electrode PP may extend in the vertical direction and be electrically connected to the information storage elements DS. A portion of the plate electrode PP may also function as an information storage element DS.

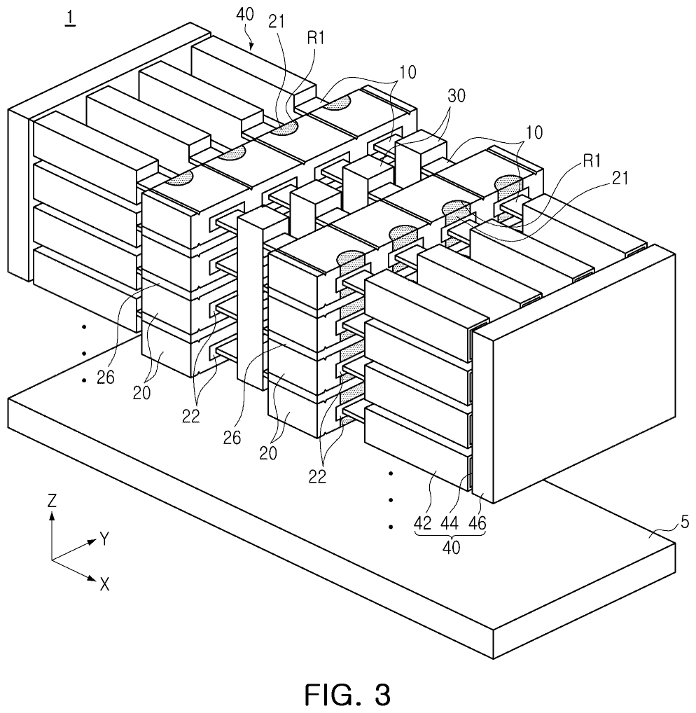

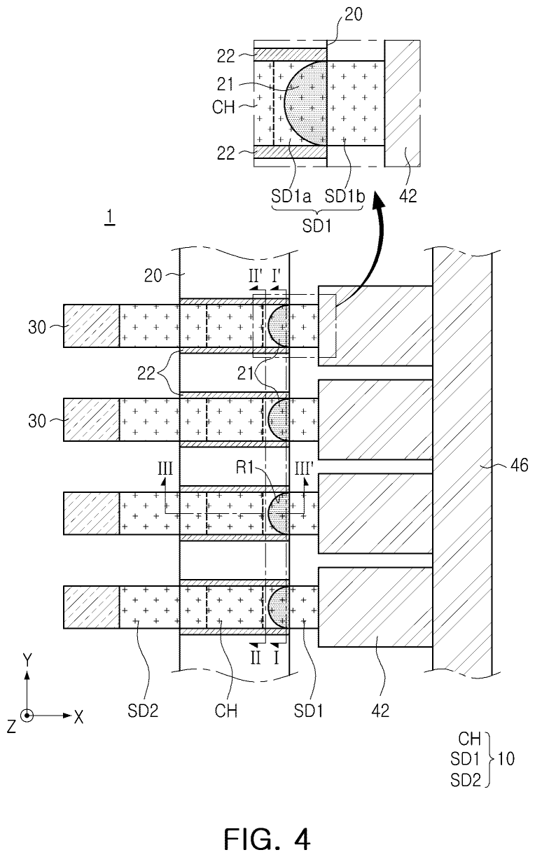

FIG. 3 is a schematic perspective view of a semiconductor device according to an example embodiment. FIG. 4 is a plan view of a semiconductor device according to an example embodiment.

Referring to FIGS. 3 and 4, the semiconductor device 1 may include active layers 10, gate electrodes 20, vertical conductive patterns 30 extending in the Z-direction, and a capacitor structure 40 disposed on a substrate 5.

The semiconductor device 1 may include, for example, an array of DRAM memory cells. The vertical conductive patterns 30 may correspond to the bit lines BL of FIG. 2, at least one of the gate electrodes 20 may correspond to the word line WL of FIG. 2, and the capacitor structure 40 may correspond to the information storage element DS and the plate electrode PP of FIG. 2.

The substrate 5 may include a semiconductor material, for example, a group IV semiconductor, a group III-V compound semiconductor, or a group II-VI compound semiconductor. For example, the group IV semiconductor may include silicon, germanium, or silicon-germanium. The substrate 5 may further include impurities. The substrate 5 may be a silicon substrate, a silicon-on-insulator (SOI) substrate, a germanium substrate, a germanium-on-insulator (GOI) substrate, a silicon-germanium substrate, or a substrate including an epitaxial layer.

The active layers 10 are disposed on the substrate 5 and may extend in the X-direction. The active layers 10 may be spaced apart from each other in the Y-direction and the Z-direction. In the plan view, the active layers 10 may have a line shape, a bar shape, or a pillar shape that intersects the gate electrodes 20 and extends in the X-direction. In an example, the active layers 10 may include a semiconductor material, for example, silicon, germanium, or silicon-germanium.

Each of the active layers 10 may include a first source/drain region SD1, a channel region CH, and a second source/drain region SD2 sequentially arranged along the X-direction. The channel region CH may be disposed between the first source/drain region SD1 and the second source/drain region SD2. The second source/drain region SD2 may be in contact with the vertical conductive pattern 30 and electrically connected to the vertical conductive pattern 30. The first source/drain region SD1 may be in contact with the first electrode 42 of the capacitor structure 40 and electrically connected to the first electrode 42. The channel region CH may be surrounded by the gate electrode 20. For example, the upper surface, lower surface, and side surfaces of the channel region CH may be surrounded by a gate electrode 20. The active layer 10 may be formed of a semiconductor material, the first source/drain region SD1 and the second source/drain region SD2 may each include impurities, and the impurities may have an n-type or p-type conductivity.

At least a portion of the first source/drain region SD1 and at least a portion of the second source/drain region SD2 may correspond to the source/drain region of the memory cell transistor MCT of FIG. 2, respectively. At least a portion of the channel region CH may correspond to the channel of the memory cell transistor MCT of FIG. 2. The second source/drain region SD2 may provide a region for directly connecting the memory cell transistor MCT to the bit line BL, and the first source/drain region SD1 may provide a region for directly connecting the memory cell transistor MCT to the information storage element DS.

In another example, the active layers 10 may include an oxide semiconductor, for example, at least one of hafnium-silicon oxide (HSO), hafnium-zinc oxide (HZO), indium-zinc oxide (IZO), indium-gallium oxide (IGO), indium-tin oxide (ITO), indium-gallium-zinc oxide (IGZO), and indium-tin-zinc oxide (ITZO).

In another example, the active layers 10 may include a two-dimensional material (2D material) in which atoms form a predetermined crystal structure and which may form a channel of the transistor. The two-dimensional material layer may include at least one of a transition metal dichalcogenide (TMD) material layer, a black phosphorous material layer, and a hexagonal boron-nitride (hBN) material layer. For example, the two-dimensional material layer may include at least one of BiOSe, Crl, WSe2, MoS2, TaS, WS, SnSe, ReS, β-SnTe, MnO, AsS, P(black), InSe, h-BN, GaSe, GaN, SrTiO, (MXene), and Janus 2D materials that may form a two-dimensional material.

In some example embodiments, the semiconductor device 1 may further include epitaxial layers grown from the active layer 10 and connected to the first source/drain region SD1 and the second source/drain region SD2 of the active layer 10, respectively.

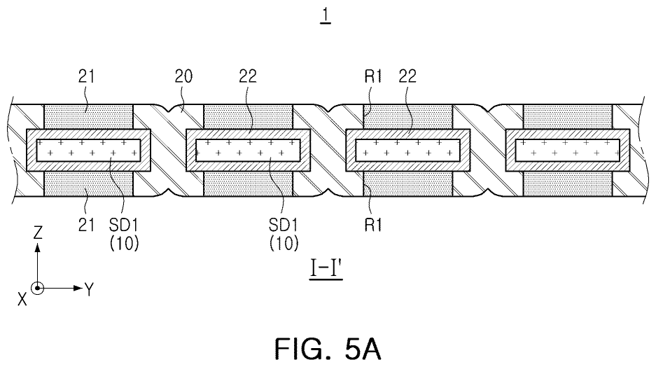

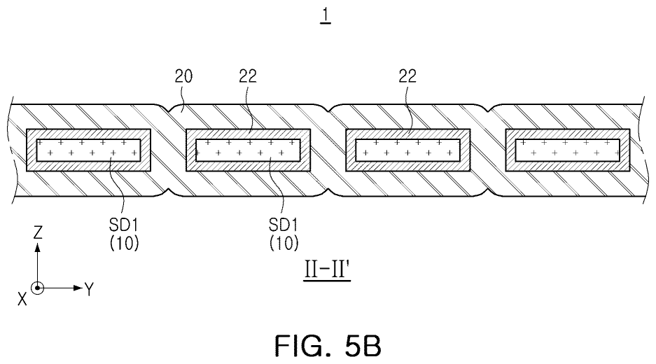

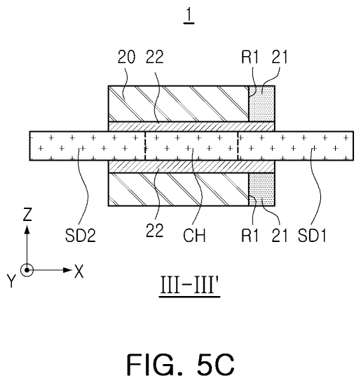

Gate electrodes 20 are disposed on the substrate 5 and may extend horizontally in the Y-direction. The gate electrodes 20 may be spaced apart from each other in the X-direction and the Z-direction. The gate electrodes 20 may be disposed between the channel regions CH of the vertically adjacent active layers 10. The gate electrodes 20 may partially overlap the first source/drain regions SD1 and the second source/drain regions SD2 of the active layers 10 in the vertical direction. In a plan view, the gate electrodes 20 may have a line shape, a bar shape, or a pillar shape extending in the Y-direction. The gate electrodes 20 may include (i.e., define or have formed therein) a dimple or a depression formed between the active layers 10 (see FIG. 5A), but example embodiments are not limited thereto.

The gate electrodes 20 may include a conductive material, and the conductive material may include at least one of a doped semiconductor material (for example, doped silicon, doped germanium, or the like), a conductive metal nitride (for example, titanium nitride, tantalum nitride, tungsten nitride, or the like), a metal (for example, tungsten, titanium, tantalum, cobalt, aluminum, ruthenium, or the like), and a metal-semiconductor compound (for example, tungsten silicide, cobalt silicide, titanium silicide, or the like). At least one of the gate electrodes 20 may correspond to the word lines WL described with reference to FIG. 2. In an example embodiment, the gate electrodes 20 may be disposed on upper and lower surfaces of each active layer 10, and two gate electrodes 20 adjacent to each active layer 10 may constitute one word line WL.

In an example embodiment, the gate electrode 20 may be disposed in a gate all around structure surrounding the active layer 10. For example, the gate electrode 20 may surround the upper surface, lower surface, and side surfaces of the active layer 10. In some example embodiments, the memory cell transistor MCT may have a single gate structure. For example, for each active layer 10, one of the gate electrodes 20 may be disposed adjacently, and one gate electrode 20 may constitute a word line WL.

FIG. 5A is a vertical cross-sectional view along line I-I′ of the semiconductor device illustrated in FIG. 4. FIG. 5B is a vertical cross-sectional view along line II-II′ of the semiconductor device illustrated in FIG. 4. FIG. 5C is a vertical cross-sectional view along line III-III′ of the semiconductor device illustrated in FIG. 4.

Referring further to FIGS. 5A to 5C, the gate electrode 20 may include (i.e., define or have formed therein) a recessed region R1. For example, in a plan view, the gate electrode 20 may include one side adjacent to the capacitor structure 40 and another side opposite to the one side and adjacent to the vertical conductive pattern 30. A recessed region R1 in the gate electrode 20 may extend along the X-direction from the one side. The recessed region R1 may overlap with the active layer 10 in a vertical direction. For example, the recessed region R1 may overlap with the first source/drain region SD1 in a vertical direction. Each gate electrode 20 may include recessed regions R1 that overlap vertically with the first source/drain regions SD1 of the active layers 10. For example, the recessed regions R1 may be spaced apart from each other in the Y-direction in a plan view. As illustrated in FIG. 5A, the recessed regions R1 may be spaced apart from each other in the vertical direction with the first source/drain region SD1 interposed therebetween.

In an example embodiment, the recessed region R1 may have a curved surface in a plan view. For example, the horizontal width of the recessed region R1 in the Y-direction may decrease as it approaches the channel region CH. In some example embodiments, the horizontal width of the recessed region R1 in the Y-direction in a plan view may be constant.

The semiconductor device 100 may further include a gate dielectric layer 22 disposed on the active layer 10 and the gate electrode 20. The gate dielectric layer 22 may cover the upper surface, lower surface, and side surface of the active layer 10. In this regard, the gate dielectric layer 22 may surround the active layer 10. A surface of the gate dielectric layer 22 may be coplanar with a surface of the gate electrode 20 and a surface of the insulating pattern 21.

The gate dielectric layer 22 may include at least one of silicon oxide, silicon nitride, a low-k material, and a high-κ material. The high-κ material indicates a dielectric material having a higher dielectric constant than silicon oxide, and the low-k material indicates a dielectric material having a lower dielectric constant than silicon oxide. The high-κ material may be, for example, a metal oxide or a metal oxynitride. The high-κ material may be one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSixOy), hafnium oxide (HfO₂), hafnium silicon oxide (HfSixOy), lanthanum oxide (La₂O₃), lanthanum aluminum oxide (LaAlxOy), lanthanum hafnium oxide (LaHfxOy), hafnium aluminum oxide (HfAlxOy), and praseodymium oxide (Pr₂O₃). The gate dielectric layer 22 may be formed as a single layer or multiple layers of the aforementioned materials.

The semiconductor device 1 may further include an insulating pattern 21 filling the recessed region R1 of the gate electrode 20. In an example embodiment, the insulating pattern 21 may have a surface that is coplanar with one side surface of the gate electrode 20 adjacent to the capacitor structure 40. The insulating pattern 21 may have a rounded side surface that is in contact with the gate electrode 20. In an example embodiment, the insulating pattern 21 may have a semicircular shape in a plan view, but example embodiments are not limited thereto. According to example embodiments, the insulating pattern 21 may have a shape such as a quadrangle or a triangle. The insulating patterns 21 may be spaced apart from each other in the Y-direction and the Z-direction. As illustrated in FIG. 4, the insulating patterns 21 may be spaced apart from each other in the Y-direction with the gate electrode 20 therebetween. In addition, as illustrated in FIG. 5A, the insulating patterns 21 may be spaced apart from each other in a vertical direction with the first source/drain region SD1 and the gate dielectric layer 22 therebetween.

The insulating pattern 21 may partially overlap with the first source/drain region SD1 in the vertical direction. For example, the first source/drain region SD1 may include a first portion SD1a that vertically overlaps with the gate electrode 20 and a second portion SD1b that does not vertically overlap with the gate electrode 20 and is spaced apart from the gate electrode 20. The second portion SD1b may not vertically overlap with the insulating pattern 21. In addition, a part of the first portion SD1a may vertically overlap with the gate electrode 20 but not vertically overlap with the insulating pattern 21. For example, the width of the insulating pattern 21 in the X-direction may be less than the width of the first portion SD1a in the X-direction. As illustrated in FIG. 5B and FIG. 5C, a part of the first portion SD1a may not overlap with the insulating pattern 21 in the vertical direction.

The insulating pattern 21 may be in contact with the gate dielectric layer 22. For example, as illustrated in FIG. 5A, the insulating pattern 21 may be in contact with the upper and lower surfaces of the gate dielectric layer 22. The width of the insulating pattern 21 in the Y-direction is illustrated to be less than the width of the gate dielectric layer 22 in the Y-direction, but example embodiments are not limited thereto. The width of the insulating pattern 21 in the Y-direction is illustrated to be the same as the width of the active layer 10 in the Y-direction, but example embodiments are not limited thereto. In an example embodiment, the insulating pattern 21 may have a cross-section perpendicular to the X-direction, and the width of the cross-section of the insulating pattern 21 may vary along the X-direction. For example, the area of the cross-section of the insulating pattern 21 may increase as distance from the channel region CH increases. The insulating pattern 21 may include at least one of an insulating material, for example, silicon nitride, silicon oxynitride, and silicon oxycarbide.

In an example embodiment, the area of the cross-section of the gate electrode 20 may vary along the X-direction. For example, as illustrated in FIGS. 5A and 5B, the gate electrode 20 may have a cross-section that is perpendicular to the X-direction, and the cross-section of the gate electrode 20 may decrease as distance from the channel region CH increases. The first source/drain region SD1 may have a cross-section that is perpendicular to the X-direction, and the ratio of the area of the cross-section of the gate electrode 20 to the area of the cross-section of the first source/drain region SD1 may vary based on distance from the channel region CH.

According to example embodiments, because the gate electrode 20 includes a recessed region R1, the area where the gate electrode 20 and the first source/drain region SD1 overlap may be reduced by the area of the recessed region R1. For example, the area where the gate electrode 20 and the first source/drain region SD1 overlap along the vertical direction may be smaller than the area where the gate electrode 20 and the second source/drain region SD2 overlap along the vertical direction. Accordingly, gate-induced drain leakage (GIDL) may be prevented or reduced. For example, current leakage from the first source/drain region SD1 to the capacitor structure 40 may be prevented or reduced.

The semiconductor device 1 may further include interlayer insulating layers 26 between the gate electrodes 20 that are vertically spaced apart and stacked. The interlayer insulating layers 26 may spatially separate vertically adjacent gate electrodes 20 and electrically insulate the same. Interlayer insulating layers 26 may include at least one of an insulating material, for example, silicon nitride, silicon oxynitride, and silicon oxycarbide.

The vertical conductive patterns 30 may extend vertically in the Z-direction on the substrate 5. The vertical conductive patterns 30 may be spaced apart from each other in the Y-direction. A plurality of active layers 10 stacked in the Z-direction may be electrically connected by one vertical conductive pattern 30. For example, the vertical conductive pattern 30 may be in contact with the second source/drain regions SD2 of the plurality of active layers 10 stacked in the Z-direction, and may be electrically connected to the second source/drain regions SD2. The vertical conductive patterns 30 may have a line shape, a bar shape, or a pillar shape extending in the Z-direction. The vertical conductive patterns 30 may include at least one of a doped semiconductor material, a conductive metal nitride, a metal, and a metal-semiconductor compound. The vertical conductive patterns 30 may correspond to the bit lines BL described with reference to FIG. 2.

The capacitor structure 40 may include a first electrode 42, a second electrode 46, and a capacitor dielectric 44 between the first electrode 42 and the second electrode 46. The capacitor structure 40 may provide a plurality of information storage elements DS as illustrated in FIG. 2 and plate electrodes PP connected to the plurality of information storage elements DS. For example, the plurality of information storage elements DS may refer to a portion of the capacitor structure 40 extending in the X-direction. The plurality of information storage elements DS may be spaced apart from each other in the Y-direction and the Z-direction. The plate electrodes PP may extend in the Z-direction and be electrically connected to the information storage elements DS. For example, the second electrode 46 may constitute the plate electrode PP.

A capacitor structure 40 may be disposed adjacent to a first source/drain region SD1 of an active layer 10. The capacitor structure 40 may be in contact with the first source/drain region SD1 of the active layer 10 and may be electrically connected to the first source/drain region SD1. For example, a first electrode 42 of the capacitor structure 40 may be in contact with the first source/drain region SD1. A portion of the second electrode 46 may protrude in the X-direction and overlap with the first electrode 42 in a vertical direction. A capacitor dielectric 44 may be disposed between the first electrode 42 and the second electrode 46. The first electrode 42 may have a cylinder shape. For example, each of the first electrodes 42 may have a cylinder shape that is open in a direction away from the first source/drain region SD1, and in example embodiments, may also have a pillar shape.

The first electrodes 42 may be nodes that are separated from each other. The first electrodes 41 may be referred to as ‘storage node electrodes.’ The first electrodes 42 may include at least one of a doped semiconductor material, a conductive metal nitride, a metal, and a metal-semiconductor compound.

The capacitor dielectric 44 may cover the first electrode 42. The capacitor dielectric 44 may include at least one of high-κ materials such as zirconium oxide (ZrO₂), aluminum oxide (Al₂O₃), and hafnium oxide (Hf₂O₃).

The second electrode 46 may cover the capacitor dielectric 44. At least a portion of the second electrode 46 may be referred to as a ‘plate electrode PP’. The second electrode 46 may include at least one of a doped semiconductor material, a conductive metal nitride, a metal, and a metal-semiconductor compound.

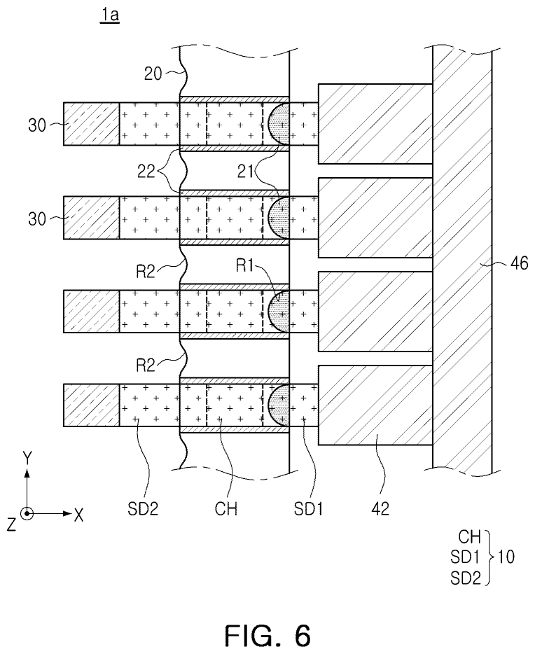

FIGS. 6 to 9 are plan views of semiconductor devices according to example embodiments.

Referring to FIG. 6, a semiconductor device 1a may include a gate electrode 20 surrounding an active layer 10. In an example embodiment, the gate electrode 20 may further include (i.e., define or have formed therein) a recessed region R2.

For example, in the plan view, the gate electrode 20 may include one side adjacent to the capacitor structure 40 and another side opposite to the one side and adjacent to the vertical conductive pattern 30. The gate electrode 20 may include (i.e., define or have formed therein) a recessed region R2 extending along the X-direction from the other side. The recessed region R2 may be disposed between active layers 10 spaced apart in the Y-direction. For example, in the plan view, the recessed regions R2 may be spaced apart from each other in the Y-direction. Although the recessed region R2 is illustrated as not vertically overlapping the active layers 10, example embodiments are not limited thereto. In example embodiments, the recessed region R2 may overlap the active layers 10 in the vertical direction. The recessed region R2 may be misaligned with the recessed region R1 in the X-direction. For example, at least a portion of the recessed region R2 may be offset from the recessed region R1 in the X-direction.

In an example embodiment, the recessed region R2 may have a curved surface in the plan view. For example, the horizontal width of the recessed region R1 in the Y-direction may decrease as distance from the channel region CH decreases. In some example embodiments, the horizontal width of the recessed region R2 in the Y-direction in the plan view may be constant.

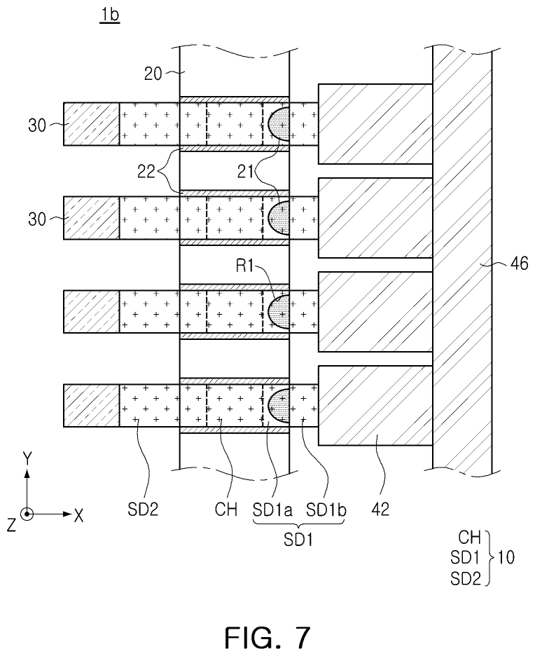

Referring to FIG. 7, a semiconductor device 1b may include an insulating pattern 21 filling the recessed region R1 of the gate electrode 20. In an example embodiment, the maximum horizontal width of the insulating pattern 21 in the Y-direction may be less than the width of the active layer 10 in the Y-direction. For example, the maximum horizontal width of the insulating pattern 21 in the Y-direction may be less than the width of the first portion SD1a of the first source/drain region SD1 in the Y-direction.

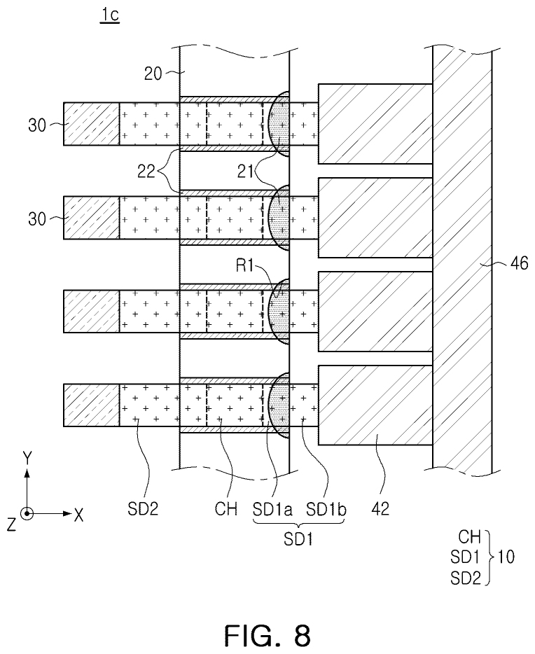

Referring to FIG. 8, a semiconductor device 1c may include an insulating pattern 21 filling the recessed region R1 of the gate electrode 20. In an example embodiment, the maximum horizontal width of the insulating pattern 21 in the Y-direction may be greater than the width of the active layer 10 in the Y-direction. For example, the maximum horizontal width of the insulating pattern 21 in the Y-direction may be greater than the width of the first portion SD1a of the first source/drain region SD1 in the Y-direction.

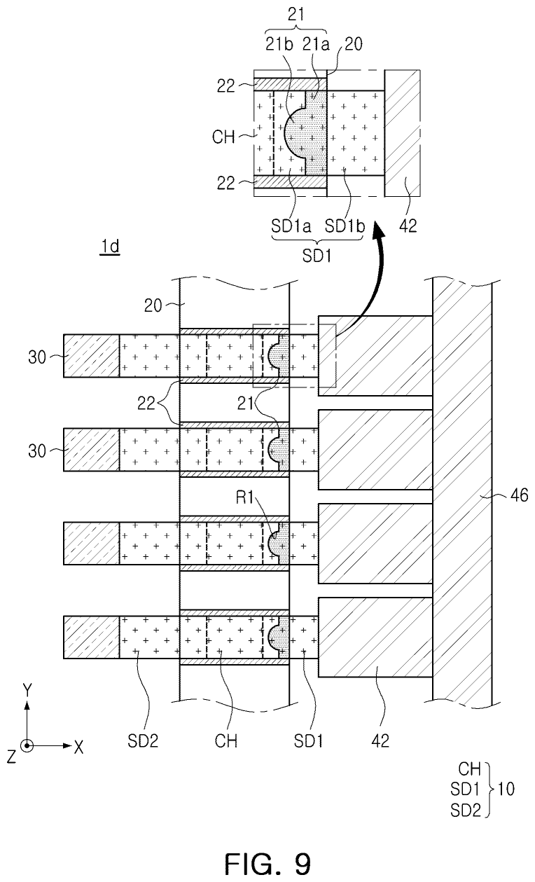

Referring to FIG. 9, a semiconductor device 1d may include an insulating pattern 21 filling the recessed region R1 of the gate electrode 20. In an example embodiment, the insulating pattern 21 may include a first portion 21a and a second portion 21b. A surface of the first portion 21a may be coplanar with a side surface of the gate electrode 20 adjacent to the first electrode 42 of the information storage structure 40. In a plan view, the first portion 21a may have a rectangular shape or a bar shape. The second portion 21b may protrude from the first portion 21a toward the channel region CH. In a plan view, the second portion 21b may have a rounded shape. In an example embodiment, the width of the second portion 21b in the Y-direction may be less than the width of the first portion 21a in the Y-direction, but example embodiments are not limited thereto.

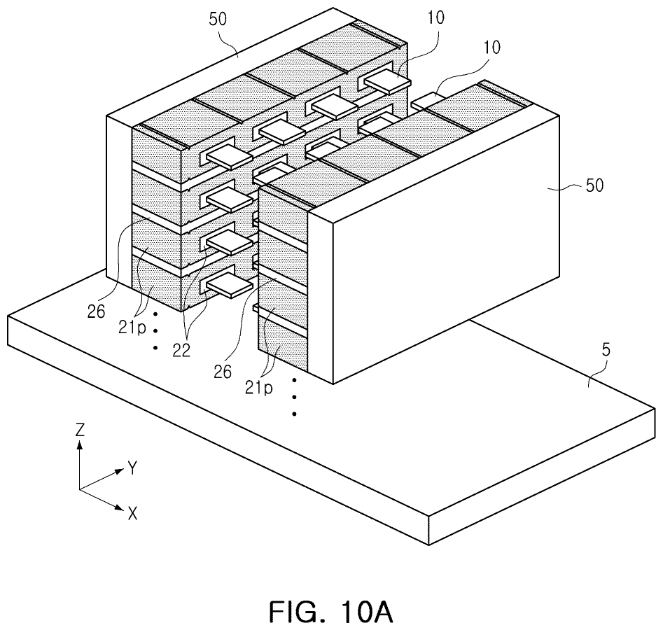

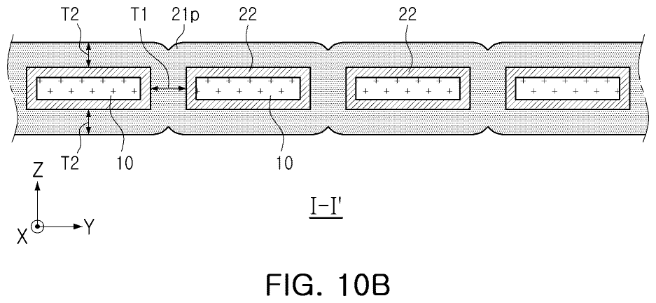

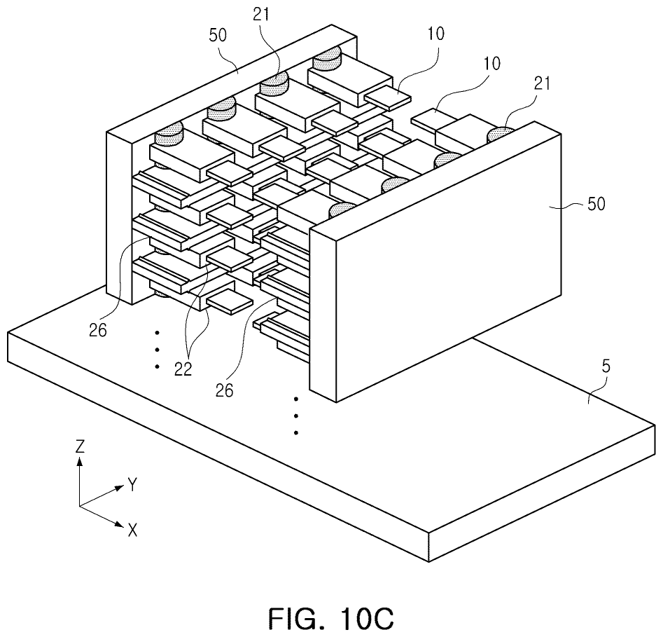

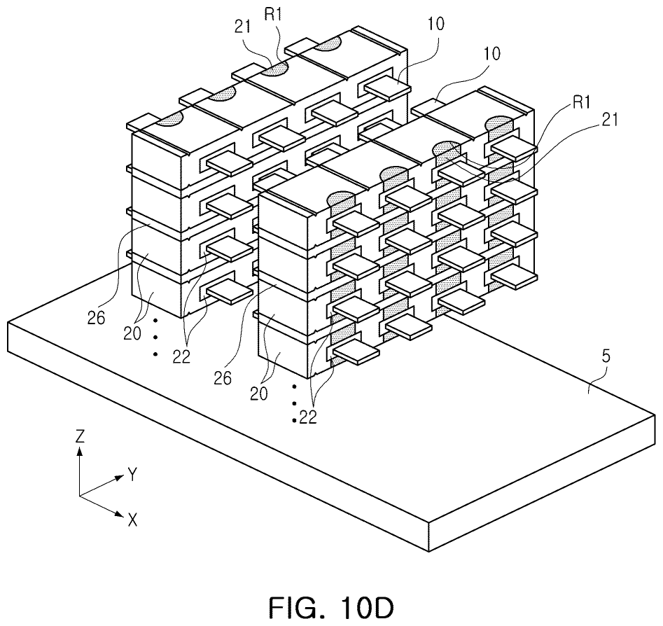

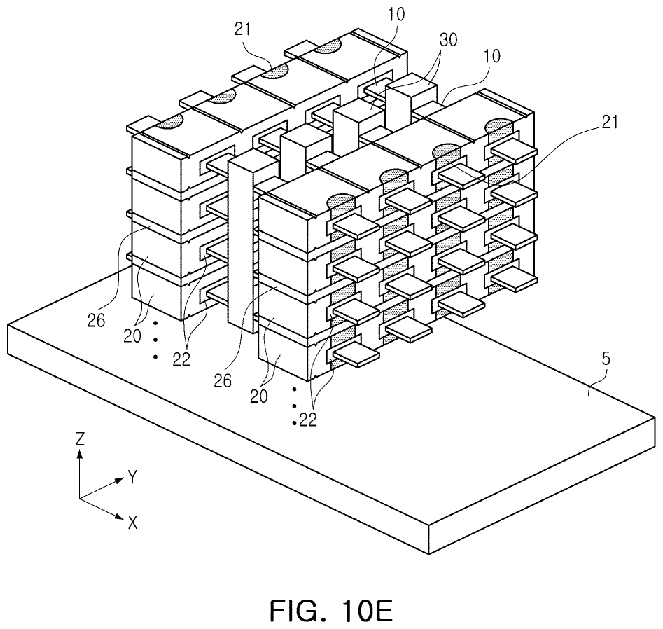

FIGS. 10A to 10E are drawings illustrating a process sequence of a method of manufacturing a semiconductor device according to an example embodiment. FIGS. 10A, 10C,10D and 10E are schematic perspective views corresponding to FIG. 3.

Referring to FIG. 10A, stack structures 21p, 22 and 26, an active layer 10, and a vertical structure 50 may be formed on a substrate 5. The stack structures 21p, 22 and 26 may include an insulating material layer 21p, a gate dielectric layer 22, and an interlayer insulating layer 26. The stack structures 21p, 22 and 26 may be formed by stacking semiconductor material layers and sacrificial layers, removing the sacrificial layers to expose the semiconductor material layers, forming gate dielectric layers 22 on the exposed semiconductor material layers, and depositing an insulating material layer 21p and an interlayer insulating layer 26 to cover the gate dielectric layers 22. The semiconductor material layers may be patterned to form active layers 10 before forming the gate dielectric layers 22. The active layers 10 may extend in the X-direction, and the active layers 10 may be partially exposed.

The insulating material layer 21p may surround the active layers 10 and may extend in the Y-direction. The gate dielectric layer 22 may be disposed between the insulating material layer 21p and the active layer 10, and may surround the active layer 10. An interlayer insulating layer 26 may be disposed between the insulating material layers 21p. The insulating material layer 21p may include a material having an etching selectivity with the gate dielectric layer 22.

The vertical structure 50 may be formed before forming the stack structures 21p, 22 and 26. The vertical structure 50 may include an insulating material, for example, at least one of silicon nitride, silicon oxynitride, and silicon oxycarbide.

FIG. 10B is a cross-sectional view of the stack structures 21p, 22 and 26 and the active layers 10 illustrated in FIG. 10A. FIG. 10B may be a vertical cross-sectional view of the semiconductor device illustrated in FIG. 4, taken along line II-II′.

Referring to FIG. 10B, the insulating material layer 21p covering the active layers 10 and the gate dielectric layers 22 extends in the Y-direction. The horizontal thickness T1 of the insulating material layer 21p between the active layers 10 may be greater than the vertical thickness T2 of the insulating material layer 21p below or above the gate dielectric layers 22.

Referring to FIG. 10C, the insulating material layer 21p may be etched to form an insulating pattern 21. For example, the insulating material layer 21p may be etched by a wet etching process. Because the insulating material layer 21p includes a material having an etching selectivity with the gate dielectric layer 22, the gate dielectric layer 22 may not be etched in the etching process. The active layer 10 and the interlayer insulating layer 26 may also not be etched by the etching process. The insulating patterns 21 may be disposed below and above respective gate dielectric layers 22 and may overlap with the active layers 10 in the vertical direction.

Referring to FIG. 10D, gate electrodes 20 covering gate dielectric layers 22 may be formed. The gate electrodes 20 may be formed by forming a metal material to cover the active layers 10, the gate dielectric layers 22, and the insulating patterns 21, and etching back the metal material so that the active layers 10 are exposed.

The gate electrodes 20 may surround the active layers 10 and may extend in the Y-direction. The gate electrodes 20 may cover the side surfaces of the insulating patterns 21. The gate electrodes 20 may have (i.e., define or have formed therein) recessed regions R1 at locations corresponding to the insulating patterns 21. The insulating patterns 21 may fill the recessed regions R1. The vertical structure 50 may be selectively removed.

Referring to FIG. 10E, vertical conductive patterns 30 may be formed that are in contact with one end of the active layers 10. The vertical conductive patterns 30 may extend in the vertical direction and may be electrically connected to the active layers 10 that are spaced apart from each other in the vertical direction.

Referring again to FIG. 3, a capacitor structure 40 may be formed at another end opposite to the one end of the active layers 10 to manufacture the semiconductor device 1. The one end of the active layers 10 may correspond to the second source/drain regions SD2, and the other end may correspond to the first source/drain region SD1. In an example embodiment, the second source/drain region SD2 may be formed by doping a portion of the active layer 10 with an impurity before forming the vertical conductive patterns 30. Before forming the capacitor structure 40, a portion of the active layer 10 may be doped with an impurity to form a first source/drain region SD1.

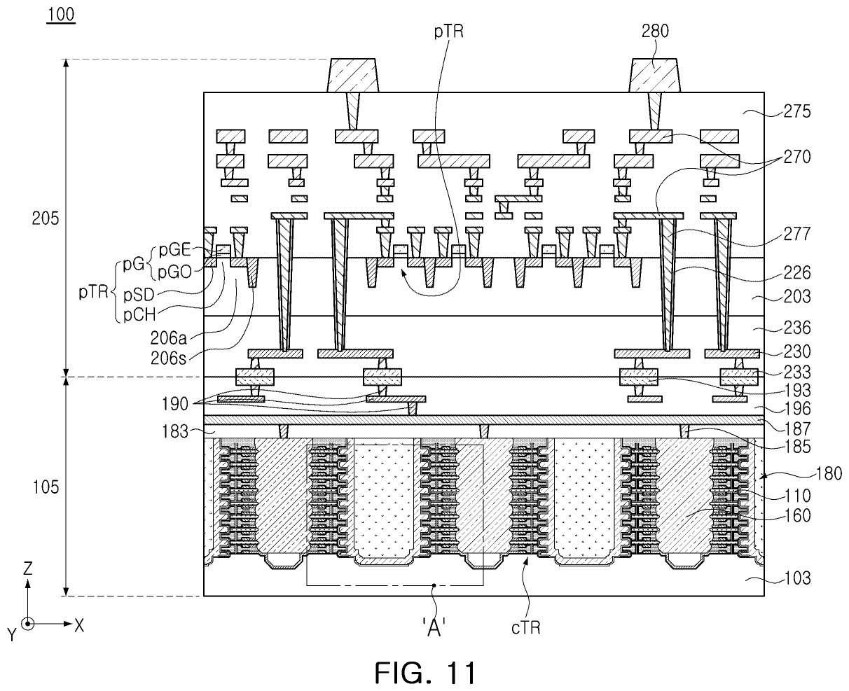

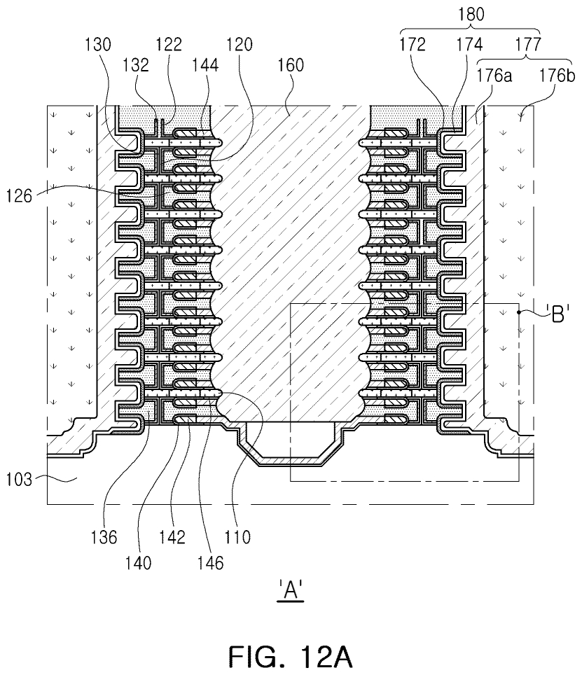

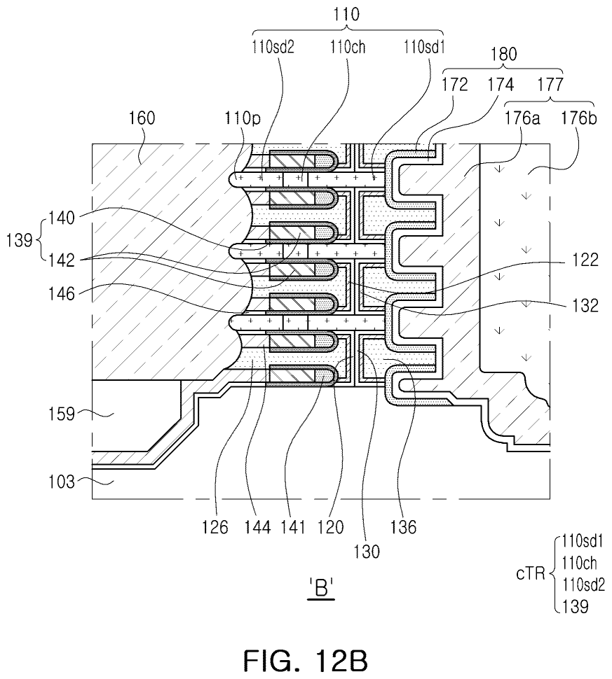

FIG. 11 is a vertical cross-sectional view of a semiconductor device according to an example embodiment. FIG. 12A is an enlarged view of a portion of the semiconductor device illustrated in FIG. 11. FIG. 12A may correspond to region A of FIG. 11. FIG. 12B is an enlarged view of a portion of the semiconductor device illustrated in FIG. 12A. FIG. 12B may correspond to region B of FIG. 12A.

Referring to FIGS. 11, 12A, and 12B, a semiconductor device 100 according to an example embodiment may include a first structure 105 and a second structure 205 vertically overlapping the first structure 105. The second structure 205 may be disposed on the first structure 105.

In an illustrative example, the first structure 105 may be the first structure ST1 described in FIG. 1. In an illustrative example, the second structure 205 may be the second structure ST2 described in FIG. 1.

The first structure 105 may be a memory region including memory cells arranged three-dimensionally, and the second structure 205 may be a peripheral region including peripheral circuits.

The first structure 105 may include a substrate 103, cell transistors cTR disposed on the substrate, vertical conductive patterns 160, and capacitor structures 180.

The capacitor structures 180 of the first structure 105 may be spaced apart from each other in the X-direction. One of the vertical conductive patterns 160 may be disposed between a pair of adjacent capacitor structures 180.

The first structure 105 may include active patterns 110 that are spaced apart from each other in the vertical direction (e.g., Z direction) and are stacked. Each of the active patterns 110 may include a first source/drain region 110sd1, a channel region 110ch, and a second source/drain region 110sd2.

The active patterns 110 may be formed of the same material as the active layers 10 described above. Each of the active patterns 110 may include a first source/drain region 110sd1, a channel region 110ch, and a second source/drain region 110sd2 corresponding to the first source/drain region SD1, the channel region CH, and the second source/drain region SD2 described above.

The first structure 105 may include gates 139 that are spaced apart from each other in the vertical direction and are stacked. The gates 139 may overlap with the channel regions 110ch of the active patterns 110 in the vertical direction. Each of the gates 139 may include a gate electrode 142 that surrounds the channel region 110ch and extends in the Y-direction, and a gate dielectric layer 140 between the gate electrode 142 and the channel region 110ch. The gate electrode 142 may have a structure that is the same as or similar to the gate electrode 20 described with reference to FIGS. 3 to 9.

The first structure 105 may further include insulating patterns 141 that overlap with the first source/drain regions 110sd1 of the active patterns 110 in the vertical direction. The insulating patterns 141 may have the same or similar structure as the insulating patterns 21 described with reference to FIGS. 3 to 9. The gate electrode 142 may include recessed regions, and the insulating patterns 141 may fill the recessed regions.

The gate electrodes 142 may include word lines in a memory such as a DRAM.

Each of the cell transistors cTR may include the first source/drain region 110sd1, the channel region 110ch, the second source/drain region 110sd2, and the gate 139.

The capacitor structures 180 may be memory cell capacitors capable of storing memory processor information. For example, the semiconductor device may be a DRAM memory device, and the memory cell capacitor structures 180 may store information. The capacitor structures 180 may correspond to the capacitor structures 40 described above in FIGS. 3 to 9. Each of the capacitor structures 180 may include first electrodes 172, a second electrode 177, and a dielectric layer 174 between the first electrodes 172 and the second electrode 177.

The first electrodes 172 may be electrically connected to the first source/drain regions 110sd1 of the active patterns 110. The first electrodes 172 may have substantially the same shape as the first electrodes 42 in FIGS. 3 to 9, but example embodiments are not limited thereto.

The second electrode 177 may include a first material layer 176a in contact with the dielectric layer 174 and a second material layer 176b in contact with the first material layer 176a. The second electrode 177 may have substantially the same shape as the second electrode 46 in FIGS. 3 to 9, but example embodiments are not limited thereto.

Hereinafter, among the capacitor structures 180 and the vertical conductive patterns 160, one adjacent capacitor structure 180 and one vertical conductive pattern 160 will be described.

The vertical conductive pattern 160 may be formed of the same material as the vertical conductive pattern 30 in FIGS. 9 to 9A.

In an example, each of the active patterns 110 may include a protrusion 110p protruding in a direction toward the vertical conductive pattern 160. The vertical conductive pattern 160 may cover the upper surface, lower surface, and side surface of the protrusion 110p.

The first structure 105 may further include a gate capping layer 144 and an insulating layer 146. The gate capping layer 144 may be disposed between the gate electrode 142 and the vertical conductive pattern 160. A portion of the gate dielectric layer 140 may be disposed between the active pattern 110 and the gate capping layer 144. The gate capping layer 144 may be spaced apart from the buffer structure 155, and an insulating layer 146 may be disposed between the gate dielectric layer 140 and the vertical conductive pattern 160. The insulating layer 146 may be in contact with the vertical conductive pattern 160. The gate capping layers 144 may include an insulating material, for example, at least one of silicon nitride, silicon oxynitride, and silicon oxycarbide.

The first structure 105 may further include an insulating layer 159 between the substrate 103 and the vertical conductive pattern 160. The insulating layer 159 may be disposed below the vertical conductive pattern 160.

The first structure 105 may further include a first buffer layer 120, a first liner 122, and a first gapfill insulating layer 126 disposed between the active patterns 110. The first buffer layer 120, the first liner 122, and the first gapfill insulating layer 126 may be in contact with the gate dielectric layer 140. For example, the first buffer layers 120 may extend horizontally on the upper and lower surfaces of the active patterns 110 and may extend vertically between the active patterns 110. The first liner 122 may be conformally disposed on the first buffer layer 120. The first gapfill insulating layer 126 may fill a space between adjacent gate dielectric layers 140. The first gapfill insulating layer 126 may be in contact with the gate capping layer 144 and the vertical conductive pattern 160. The first buffer layer 120 and the first gap-fill insulating layer 126 may include silicon oxide, and the first liner 122 may include silicon nitride.

The first structure 105 may further include a second buffer layer 130, a second liner 132, and a second gap-fill insulating layer 136 disposed between the active patterns 110. The second buffer layer 130, the second liner 132, and the second gap-fill insulating layer 136 may be in contact with the first electrode 172. For example, the second buffer layers 130 may extend horizontally on the upper and lower surfaces of the active patterns 110, and may extend vertically between the active patterns 110. The second liner 132 may be conformally disposed on the second buffer layer 130. The second gapfill insulating layer 136 may be disposed on the second liner 132 and may fill a space between adjacent active patterns 110. The first gapfill insulating layer 126 and the second gapfill insulating layer 136 may correspond to the interlayer insulating layer 26 illustrated in FIG. 3. The second buffer layer 130 and the second gapfill insulating layer 136 may include silicon oxide, and the second liner 132 may include silicon nitride.

The first structure 105 may further include an insulating layer 183 covering the vertical conductive patterns 160 and the capacitor structures 180, contact plugs 185 penetrating the insulating layer 183 and connected to the vertical conductive patterns 160, and a conductive line 187 disposed on the insulating layer 183 and connected to the contact plugs 185.

The conductive line 187 may extend in the X-direction. The conductive line 187 may electrically connect the vertical conductive patterns 160 arranged in the X-direction through the contact plugs 185.

The first structure 105 may further include an insulating structure 196 on the conductive line 187, wiring structures 190 embedded in the insulating structure 186, and first bonding pads 193 having an upper surface that is coplanar with an upper surface of the insulating structure 196.

The second structure 205 may include peripheral circuits such as a sense amplifier and a sub word line driver within the second bank area BA2 described in FIG. 1. For example, the second structure 205 may include peripheral transistors pTR that may configure the peripheral circuit. For example, the first source/drain regions 110sd1 of the cell transistors cTR disposed within the first structure 105 may be electrically connected to the peripheral transistors pTR that may configure the sense amplifier disposed within the second structure 205 through the vertical conductive pattern 160 and the conductive line 187.

In FIG. 11, the electrical connection relationship between the peripheral transistors pTR and the cell transistors cTR is an illustrative example, and example embodiments are not limited to the arrangement structure illustrated in FIG. 11.

The second structure 205 may further include a semiconductor body 203, a device isolation region 206s defining a peripheral active region 206a on the semiconductor body 203, peripheral source/drain regions pSD disposed within the peripheral active region 206a, a peripheral channel region pCH between the peripheral source/drain regions pSD, a peripheral gate pG including a peripheral gate dielectric layer pGO and a peripheral gate electrode pGE sequentially disposed on the peripheral channel region pCH.

Each of the peripheral transistors pTR may include the peripheral source/drain regions pSD, the peripheral channel region pCH, and the peripheral gate pG.

The second structure 205 may further include a lower insulating layer 236 below the semiconductor body 203, a redistribution structure 230 embedded in the lower insulating layer 236, and second bonding pads 233 connected to the redistribution structure 230 and having lower surfaces coplanar with the lower surface of the lower insulating layer 236.

The second bonding pads 233 may be in contact with and bonded to the first bonding pads 193. The first and second bonding pads 193 and 233 may include a metal material, for example, copper.

The second structure 205 may further include an upper insulating structure 275 on the semiconductor body 203, a peripheral wiring structure 270 embedded in the upper insulating structure 275 and electrically connected to the peripheral transistors pTGR constituting the peripheral circuit, and upper wirings 280 on the upper insulating structure 275.

The second structure 205 may further include through-vias 277 penetrating the semiconductor body 203 and electrically connecting the peripheral wiring structures 270 and the redistribution structure 230, and insulating spacers 226 on side surfaces of the through-vias 277.

As set forth above, according to example embodiments, because a gate electrode or a first source/drain region includes (i.e., defines or has formed therein) a recessed region, the area of overlapping between the gate electrode and the first source/drain region may be reduced by the area of the recessed region. Accordingly, current leakage from the first source/drain region may be prevented or reduced.

While aspects of example embodiments have been illustrated and described above, it will be apparent to those skilled in the art that modifications and variations could be made without departing from the scope of the present inventive concept as defined by the appended claims.

What is claimed is:

1. A semiconductor device comprising:
an active layer extending in a first horizontal direction, the active layer comprising a first source/drain region, a channel region, and a second source/drain region sequentially arranged along the first horizontal direction;
a bit line extending in a vertical direction and connected to the first source/drain region;
an information storage structure connected to the second source/drain region;
a gate electrode surrounding the active layer and extending in a second horizontal direction intersecting the first horizontal direction, wherein the gate electrode includes a first recessed region overlapping the first source/drain region along the vertical direction;
an insulating pattern filling the first recessed region; and
a gate dielectric layer provided between the active layer and the gate electrode, and surrounding the active layer.

2. The semiconductor device of claim 1, wherein an area where the gate electrode and the first source/drain region overlap along the vertical direction is smaller than an area where the gate electrode and the second source/drain region overlap along the vertical direction.

3. The semiconductor device of claim 1, wherein the first recessed region extends along the first horizontal direction from a side surface of the gate electrode adjacent to the first source/drain region.

4. The semiconductor device of claim 1, wherein the insulating pattern contacts the gate dielectric layer.

5. The semiconductor device of claim 1, wherein the insulating pattern contacts the gate electrode and has a rounded side surface.

6. The semiconductor device of claim 1, wherein the insulating pattern comprises a first portion having a surface that is coplanar with a side surface of the gate electrode and a second portion protruding from the first portion toward the channel region.

7. The semiconductor device of claim 6, wherein a width of the second portion along the second horizontal direction is less than a width of the first portion along the second horizontal direction.

8. The semiconductor device of claim 1, wherein a width of the first recessed region along the second horizontal direction decreases as proximity to the channel region increases.

9. The semiconductor device of claim 1, wherein a second recessed region is formed in the gate electrode and overlaps the second source/drain region along the second horizontal direction.

10. The semiconductor device of claim 9, wherein the second recessed region extends along the first horizontal direction from a side surface of the gate electrode adjacent to the second source/drain region.

11. The semiconductor device of claim 9, wherein the first recessed region is offset from the second recessed region along the first horizontal direction.

12. The semiconductor device of claim 1, wherein a maximum width of the first recessed region along the second horizontal direction is different from a width of the first source/drain region along the second horizontal direction.

13. A semiconductor device comprising:
an active layer extending in a first horizontal direction, the active layer comprising a first source/drain region, a channel region, and a second source/drain region sequentially arranged along the first horizontal direction;
a bit line extending in a vertical direction and connected to the first source/drain region;
an information storage structure connected to the second source/drain region;
a gate electrode surrounding the active layer and extending in a second horizontal direction intersecting the first horizontal direction; and
a gate dielectric layer provided between the active layer and the gate electrode, and surrounding the active layer,
wherein the gate electrode includes a recessed region overlapping the first source/drain region along the vertical direction,
wherein the first source/drain region has a first cross-section perpendicular to the first horizontal direction,
wherein the gate electrode has a second cross-section perpendicular to the first horizontal direction, and
wherein a ratio of an area of the second cross-section to an area of the first cross-section decreases as distance from the channel region increases.

14. The semiconductor device of claim 13, wherein the area of the second cross-section of the gate electrode decreases as distance from the channel region increases.

15. The semiconductor device of claim 13, wherein the area of the first cross-section is constant between the channel region and the information storage structure.

16. The semiconductor device of claim 13, further comprising an insulating pattern filling the recessed region.

17. The semiconductor device of claim 16, wherein the insulating pattern has a third cross-section perpendicular to the first horizontal direction, and
wherein an area of the third cross-section increases as distance from the channel region increases.

18. A semiconductor device comprising:
active layers extending in a first horizontal direction and spaced apart from each other along a second horizontal direction intersecting the first horizontal direction, the active layers comprising first source/drain regions, second source/drain regions, and channel regions provided between the first source/drain regions and the second source/drain regions along the first horizontal direction;
bit lines extending in a vertical direction and connected to the first source/drain regions of the active layers;
an information storage structure connected to the second source/drain regions of the active layers;
a gate electrode surrounding the active layers and extending in the second horizontal direction, wherein the gate electrode includes recessed regions overlapping the first source/drain regions of the active layers along the vertical direction;
insulating patterns filling the recessed regions; and
gate dielectric layers provided between the active layers and the gate electrode, and surrounding the active layers.

19. The semiconductor device of claim 18, wherein the insulating patterns are spaced apart from each other along the second horizontal direction.

20. The semiconductor device of claim 18, wherein the insulating patterns comprise upper insulating patterns provided on the first source/drain regions and lower insulating patterns provided below the first source/drain regions, and
wherein the gate dielectric layers are in contact with the upper insulating patterns and the lower insulating patterns.
